(19) United States
(12) Patent Application Publication
(10) Pub. No.: US 2025/0140639 A1
(43) Pub. Date: May 1, 2025

(54) Integrated Circuit with Enhanced Thermal Dissipation Structure

(71) Applicant: Taiwan Semiconductor Manufacturing Company, Ltd., Hsin-Chu (TW)

(72) Inventors: Che Chi Shih, Taoyuan City (TW); Ku-Feng Yang, Hsinchu County (TW); Szuya Liao, Hsinchu (TW)

(21) Appl. No.: 18/499,870

(22) Filed: Nov. 1, 2023

(51) Int. Cl. H01L 23/373; H01L 21/8238; H01L 23/00; H01L 27/088

(52) U.S. Cl. CPC H01L 23/3732; H01L 24/29; H01L 24/32; H01L 24/83; H10D 84/0165; H10D 84/038; H10D 84/83; H01L 2224/29193; H01L 2224/32145; H01L 2224/83

(57) ABSTRACT

The present disclosure provides an integrated circuit (IC) structure in accordance with some embodiments. The IC structure includes a circuit structure having semiconductor devices formed on a first substrate, an interconnect structure over the semiconductor devices; and a thermal dissipation structure formed on a second substrate. The second substrate is boned to the circuit structure such that the thermal dissipation structure is interposed between the first and second substrates. The thermal dissipation structure includes a diamond-like carbon (DLC) layer. The DLC layer includes a bottom portion having large grain sizes and a top portion having fine DLC grain sizes.

### BACKGROUND

Many of the technological advances have occurred in the field of 3D IC packaging, which involves stacking and bonding multiple chips together. Each chip includes at least one functional IC, such as an IC configured to perform a logic function, a memory function, a digital function, an analog function, a mixed signal function, a radio frequency (RF) function, a I/O function, a communications function (e.g., provides support for wired communications and/or wireless communications by implementing desired communication protocols, such as 5G (i.e., 5th generation) wireless communications protocols, Ethernet communications protocols, IB communications protocols, etc.), a power management function, other function, or combinations thereof, memory devices, and some of these involve capacitors.

With continued advances in 3D IC stacking technology, integrated chips may experience various issues including thermal dissipation issue, which may further cause other issues, such as bonding and stress issues. Therefore, while existing 3DIC structures and the method making the same are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 illustrates a cross-sectional view of an integrated circuit (IC) structure, according to various aspects of the present disclosure.

FIGS. 2A-2B illustrate a flowchart of a method to form the IC structure of FIG. 1, in portion or in entirety, according to various aspects of the present disclosure.

FIGS. 3-10 illustrate cross-sectional views of an IC structure at various intermediate stages of fabrication and processed in accordance with the method of FIGS. 2A-2B according to an embodiment of the present disclosure.

FIG. 11 is a flowchart of a method to form the IC structure, in portion or in entirety, according to various aspects of the present disclosure.

FIGS. 12-14 illustrate cross-sectional views of an IC structure at various intermediate stages of fabrication and processed in accordance with the method of FIG. 11 according to an embodiment of the present disclosure.

FIG. 15 illustrates a cross-sectional view of an IC structure, according to various aspects of the present disclosure.

FIG. 16 is a flowchart of a method to form the IC structure of FIG. 15, in portion or in entirety, according to various aspects of the present disclosure.

FIGS. 17-26 illustrate cross-sectional views of an IC structure at various intermediate stages of fabrication and processed in accordance with the method of FIG. 16 according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure relates to an integrated circuit (IC) structure and a method of making the same, more specifically a complimentary field-effect transistor (CFET) device with enhanced thermal dissipation structure. The present disclosure also relates to methods and structures directed to an IC structure having advanced packaging structure, such as a three-dimensional IC (3DIC) structure, and a method making the same. The 3DIC structures are stacked structures with heterogenous integration, for example having logic devices stacked over memory devices, or vice versa. Especially, in the disclosed embodiment, the 3DIC structure includes a CFET structure that includes n-type FETs (nFETs) and p-type FET (pFETs) vertically stacked over each other.

In the disclosed embodiments, the IC structure includes a transistor structure having multiple vertically stacked transistors, each of which includes multiple vertically stacked nanowires or nanosheets as channels, and a gate structure wrapping around each of the channels. More specifically, the IC structure includes a complementary field-effect transistor (CFET) structure and the method of making the CFET. The CFET may include N-type FETs vertically over P-type FETs or P-type FETs vertically over the N-type FET.

In some embodiments, the IC structure includes a carrier substrate bonded to another substrate having integrated circuits formed thereon. The carrier substrate further includes a thermal dissipation structure formed thereon and configured between the integrated circuit and the carrier substrate to provide thermal dissipation. It is understood that the provided structures are only some embodiments, and the IC structure may include more than two semiconductor structures bonded together with similar bonding structures. The IC structure includes a thermal dissipation structure of a diamond-like carbon (DLC) layer having a top portion with fine grain sizes. In some embodiments, the thermal dissipation structure of DLC includes a graded structure with grain size of DLC layer decreasing from bottom to top. Thus, a top surface of the DLC layer is natural planar.

A DLC layer is formed on the carrier substrate with uneven grain size. Especially, forming the DLC layer includes forming a bottom portion having large grain sizes and then forming a top portion having fine grain sizes less than the large grain sizes. The DLC layer has higher thermal conductivity. However, the DLC is difficult to be planarize due to large grain size and high hardness. In the disclosed DLC layer, the top portion has fine grain sizes with reduced roughness and improved flatness.

The process conditions to form the disclosed DLC layer is controlled to form the DLC layer with varying grain sizes. The DLC layer includes a bottom portion with large grain size and a top portion with small grain size. In the disclosed embodiments, the bottom portion of the DLC layer includes grain sizes greater than 500 nm; and the top portion of the DLC layer includes grain sizes less than 500 nm. In furtherance of the embodiments, the bottom portion of the DLC layer includes grain sizes ranging between 500 nm and 5000 nm; and the top portion of the DLC layer includes grain sizes ranging between 5 nm and 500 nm.

The process conditions are described below according to some embodiments. In some embodiments, the DLC layer is formed by a suitable method, such as chemical vapor deposition (CVD), such as plasma CVD, other suitable method or a combination thereof. The CVD process is implemented with precursor includes carbon-containing chemical, such as benzene (C₆H₆)-nitrogen mixtures. During the deposition (such as CVD) process, the bottom portion is deposited with a first pressure (processing chamber pressure) P1 in a first duration and the top portion is deposited with a second pressure P1 in a second duration. P2 is greater than P2. In some embodiments, P1 is less than 5 Torr and the second pressure P2 is greater than 5 Torr. In some embodiments, the first pressure P1 ranges between 1 mTorr and 5 Torr, and the second pressure P2 ranges between 5 Torr and 50 Torr. In some embodiments, depositing the bottom portion of the DLC layer includes depositing the bottom portion of the DLC layer with a first deposition temperature T1; and the depositing the top portion of the DLC layer includes depositing the top portion of the DLC layer with a second deposition temperature T2 less than T1. In some embodiments, the first temperature T1 ranges between 400° C. and 1200° C. and the second temperature T2 ranges between 100° C. and 1200° C. In some embodiments, depositing each of the bottom portion and the top portion of the DLC layer includes performing a CVD process with a radio fervency (RF) power ranging between 50 W and 50 kW.

In some embodiments, such DLC layer has a thickness ranging between 1 μm and 20 μm, and the top surface of the DLC layer has a surface roughness less than 0.5 μm. The roughness is defined as the maximum height difference cross the top surface of the DLC layer.

In some embodiments, the disclosed IC structure is formed by a proper procedure through various fabrication stages, such as a monolithic process. The monolithic process is described below according to some embodiments. The semiconductor stack of Si/SiGe is formed on the first substrate and is patterned to form fin active regions, dummy gate stacks are formed by deposition and patterning, the source/drain (S/D) regions are recessed by etch, the bottom gate isolation layer is formed, inner spacers are formed by deposition and etch, bottom S/D features are formed by epitaxial growth, bottom S/D isolation layer is formed, top S/D features are formed on the bottom S/D isolation layer, dummy gate is removed, the SiGe layers are removed by etch to release channels, the bottom metal gate stacks are formed to wrap around the bottom channels, the top metal gate stacks are formed to wrap around the top channels, self-aligned cap (SAC) is formed and interconnect structure is formed.

The DLC layer is formed on a second substrate (carrier substrate) by the disclosed method, chemical mechanical polishing (CMP) process is applied to the DLC layer, and the second substrate is bonded to the first substrate. Since the disclosed DLC layer includes DLC with fine grain size to top, the top surface is substantially planar and render the CMP process is achievable with enhanced flatness.

The first and second substrates are bonded together such that the DLC layer of the second substrate is directly bonded to the frontside of the first substrate. After bonding, the first substrate is thinned down from the backside and a backside interconnect structure is formed on the backside of the first substrate.

The present disclosure also provides some alternative embodiments of the IC structure and the method making the same. In some embodiments, the IC structure includes a first substrate bonded to a second substrate, and each substrate having a stack of first semiconductor layers and second semiconductor layers alternative stacked. Each substrate further includes a thermal dissipation structure formed thereon and configured between the two substrates bonded together to provide bonding interface and thermal dissipation. In the furtherance of the embodiments, a DLC layer is formed on the first substrate and the second substrate, respectively using the disclosed method described above, and then the first and second substrates are bonded together through the DLC layers. Then the first substrate is thinned down, CFET devices and interconnect structure are formed on the first substrate from the backside with similar procedure described above, such as a monolithic process. In this case, The DLC layers in the bonding interface serve as the isolation feature between the top devices and the bottom devices in addition to the thermal dissipation structure and bonding structure.

In some embodiments, the first substrate is a semiconductor substrate such as a silicon substrate while the second substrate is a semiconductor substrate or alternatively a dielectric substrate such as one of a silicon nitride substrate, a silicon oxide substrate and an aluminum oxide substrate.

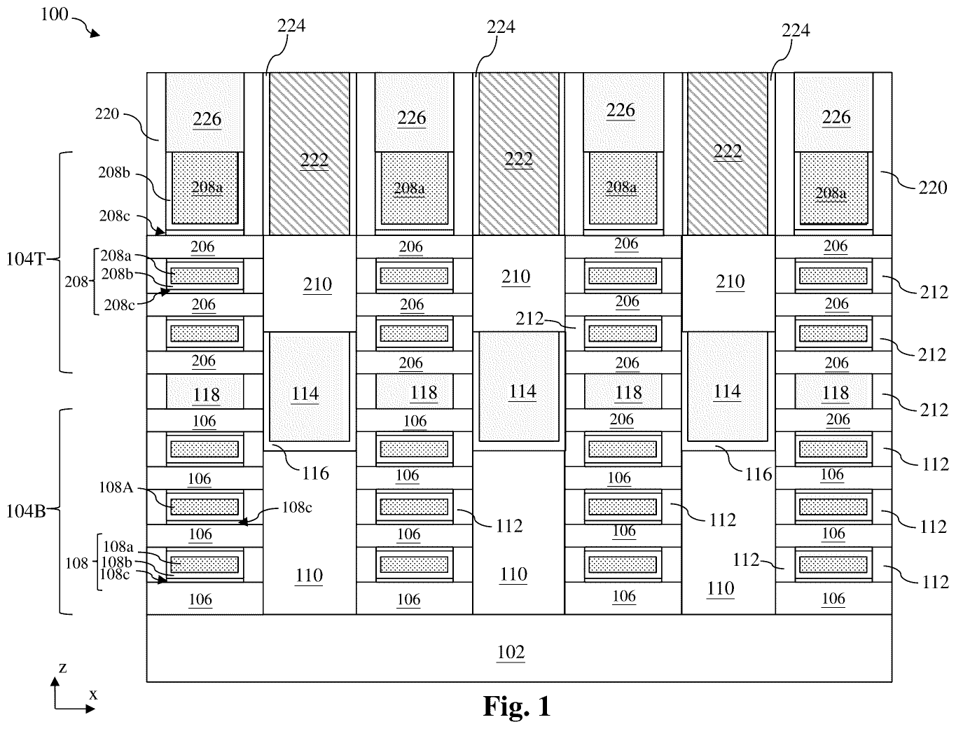

The IC structure with a DLC layer and the method making the same are further described below in detail. The IC structure formed by a monolithic process is first described below according to some embodiments. FIG. 1 is a sectional view of an IC structure 100 having CFETs according to some embodiments.

Referring to FIG. 1, the IC structure 100 having CFETs is formed by a monolithic method. As an exemplary embodiment, FIG. 1 illustrates CFET devices formed a substrate 102, in which, an n-type FET (NFET) and a p-type FET (PFET) are vertically stacked on each other with reduced circuit area and improved device performance. A CFET device can be formed in any suitable procedure, such as monolithic process, sequential process, parallel process, other suitable process, or a combination thereof. Take the monolithic process as an example. In the monolithic process, both NFETs and PFETs are formed on the same substrate, such as NFET being formed first and PFET being formed thereafter on the same substrate 102.

The IC structure 100 includes various field effect transistors formed on the substrate 102, Each FET device has multiple channels vertically stacked, such as gate-all-around (GAA) structure. Especially bottom devices 104B (such as PFETs), and top devices 104T (such as NFETs) are vertically stacked on each other.

More specifically, the bottom devices 104B of the IC structure 100 include multiple channels 106; gate stacks 108 wrapping around the channel 106; and source/drain (S/D) features 110 disposed on both sides of the channels 106 and connecting to the vertically stacked channels 106. The bottom devices 104B also includes inner spacers 112 interposed between the gate stacks 108 and the S/D features 110 to provide isolation therebetween. The inner spacers 112 include one or more dielectric material, such as silicon oxide, silicon nitride, other suitable dielectric material or a combination thereof.

The gate stacks 108 further includes a gate dielectric layer 108b and a gate electrode 108a disposed on the gate dielectric layer. In the present embodiment, the gate dielectric layer 108b includes a high-k dielectric material and the gate electrode 108a includes metal or metal alloy. In some examples, the gate electrode 108a may include a number of sub-layers. The high-k dielectric material may include metal oxide, metal nitride, such as LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr) TiO₃ (BST), Al₂O₃, Si₃N₄, oxynitrides (SiON), or other suitable dielectric materials. The gate electrode 108a may include Ti, Ag, Al, TiAlN, TaC, TaCN, TaSiN, Mn, Zr, TiN, TaN, Ru, Mo, Al, WN, Cu, W, Ru, Co, any suitable conductive materials, or a combination thereof. In some embodiments, different metal materials are used for nFET and pFET devices with respective work functions to enhance device performance. In some embodiments, the gate stacks 108 may further include an interfacial layer 108c interposed between the channels 106 and the high-k dielectric material for improved integration. The interfacial layer 108c may include silicon oxide.

Similarly, the top devices 104T of the IC structure 100 include multiple channels 206; gate stacks 208 wrapping around the channel 206; and source/drain (S/D) features 210 disposed on both sides of the channels 206 and connecting to the vertically stacked channels 206. The bottom devices 104B also includes inner spacers 212 interposed between the gate stacks 208 and the S/D features 210 to provide isolation therebetween. The inner spacers 212 include one or more dielectric material, such as silicon oxide, silicon nitride, other suitable dielectric material or a combination thereof.

The gate stacks 208 further includes a gate dielectric layer 208b and a gate electrode 208a disposed on the gate dielectric layer. In the present embodiment, the gate dielectric layer 208b includes a high-k dielectric material and the gate electrode 208a includes metal or metal alloy. In some examples, the gate electrode 208a may include a number of sub-layers. In some embodiments, different metal materials are used for nFET and pFET devices with respective work functions to enhance device performance. In some embodiments, the gate stacks 208 may further include an interfacial layer 208c interposed between the channels 206 and the high-k dielectric material for improved integration. The interfacial layer 208c may include silicon oxide.

The top devices 104T (such as NFETs) and the bottom devices 104B (such as PFETs) are vertically stacked and isolated from each other by isolation features, such as S/D isolation features 114 of one or more dielectric material, and gate isolation layer 118 of one or more dielectric material. In some embodiments, an etch stop layer 116 may be disposed to surround the S/D isolation feature 114 and includes different dielectric material to achieve etch selectivity.

The IC structure 100 further includes gate spacers 220 of one or more dielectric material disposed on sidewalls of the gate stacks 208; S/D contacts 222 of one or more conductive material landing on the S/D features 210 to couple the S/D features 210 to a power supply; and self-aligned cap (SAC) 226 of one or more dielectric material aligned to and landing on the gate stack 208. The S/D contacts 222 may be further surrounded by a barrier layer 224 of one or more dielectric material or alternative conductive material. In some examples, the barrier layer 224 includes conductive material(s), such as a titanium film and a titanium nitride film or tantalum film and a tantalum nitride film. In some other examples, the barrier layer 224 includes dielectric material(s), such as a silicon nitride, other suitable dielectric material or a combination thereof. In this case, the dielectric layer is deposited and is etched by plasma etching process so to remove the bottom portion of the barrier layer in order to have good electrical routing.

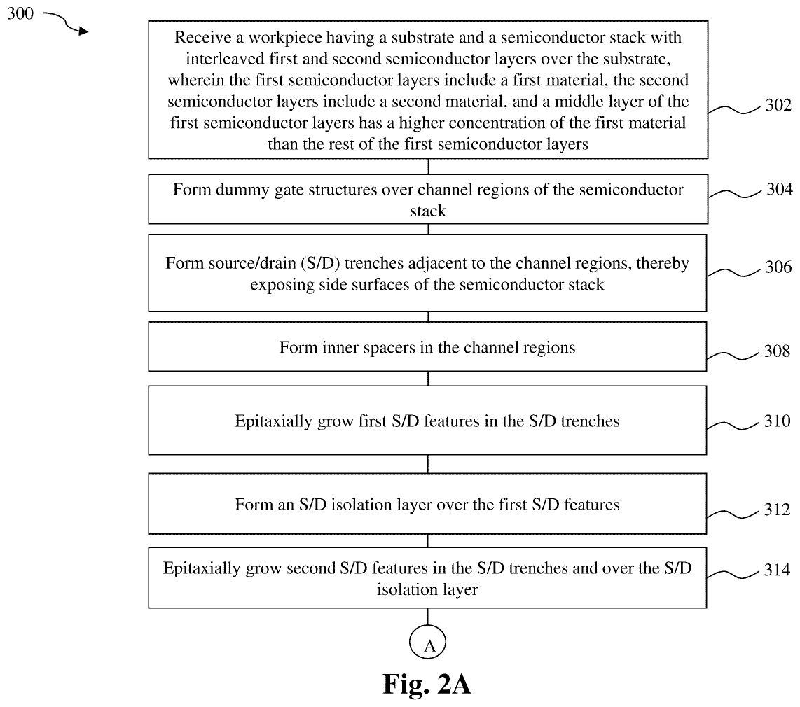

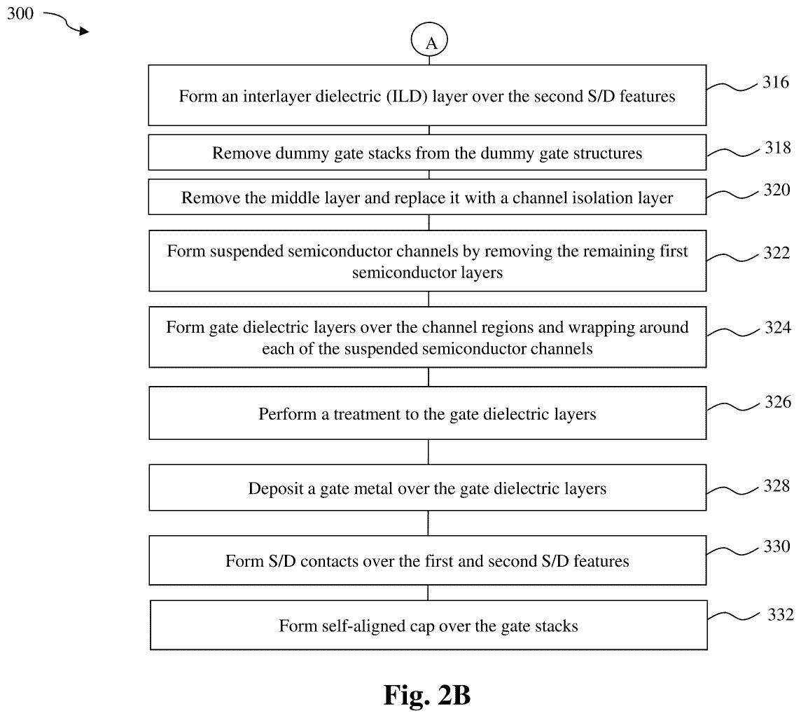

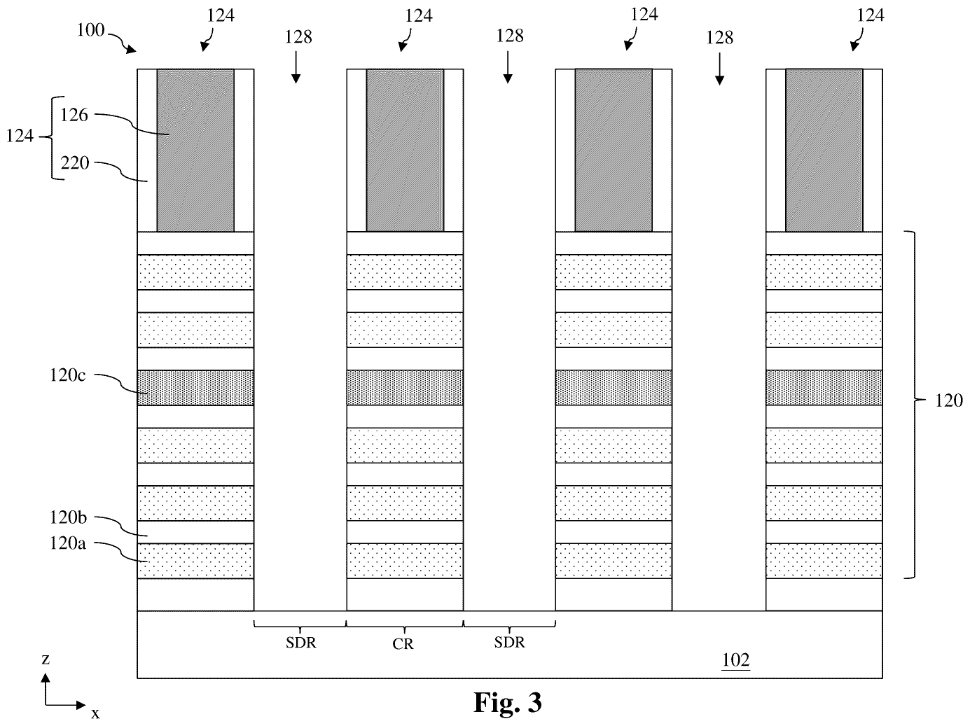

FIGS. 2A and 2B are a processing flowchart of a method 300 making the IC structure 100. FIGS. 3 through 11 are sectional views of the IC structure 100 at various fabrication stages according to some embodiments. The IC structure 100 and the method 300 are collectively described below with reference to those figures.

Referring to FIGS. 2A and 3, at operation 302, the method 300 receives or is provided with a workpiece having a substrate 102 and a semiconductor stack 120 with interleaved first and second semiconductor layers 120a, 120b over the substrate 102. The first semiconductor layers 120a include a first semiconductor material, the second semiconductor layers 120b include a second semiconductor material, and a middle layer 120c of the first semiconductor layers 120a has a higher concentration of the first semiconductor material than the rest of the first semiconductor layers 120a. The first and second semiconductor layers are patterned to form one or more semiconductor stack as active regions, such as fin active regions.

In the disclosed embodiments, the substrate 102 is a semiconductor substrate, such as a silicon substrate. In some other embodiments, the substrate 102 includes germanium, silicon germanium or other proper semiconductor materials. The substrate 102 may alternatively be made of some other suitable elementary semiconductor, such as diamond or germanium; a suitable compound semiconductor, such as silicon carbide, indium arsenide, or indium phosphide; or a suitable alloy semiconductor, such as silicon germanium carbide, gallium arsenic phosphide, or gallium indium phosphide.

In some embodiments, the first semiconductor material is silicon germanium, the second semiconductor is silicon, and the middle layer 120c include silicon germanium and has a high concentration of germanium than the rest of the first semiconductor layers 120a.

At operation 304, the method 300 forms dummy gate structures 124 over channel regions (CR) of the semiconductor stack 120. The dummy gate structures 124 include gate spacers 220 and dummy gate stacks 126. At operation 306, the method 300 forms source/drain (S/D) trenches 128 adjacent to the channel regions CR, thereby exposing side surfaces of the semiconductor stack 120.

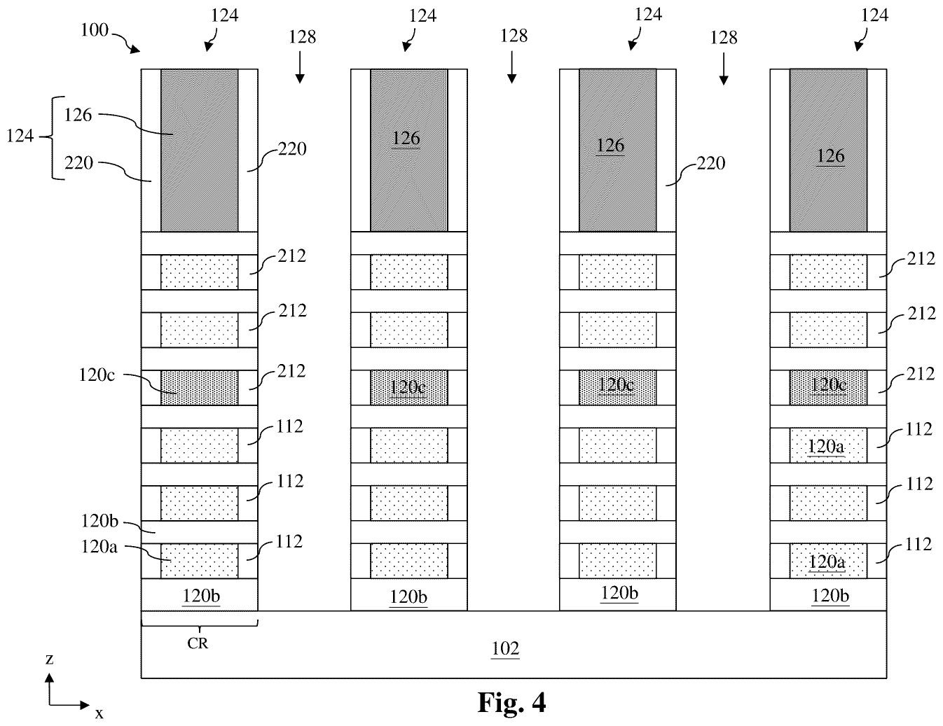

Referring to FIGS. 2A and 4, at operation 308, the method 300 form inner spacers 112 in the channel regions CR by a method such as a procedure that includes selective etch the first semiconductor layers 120a, depositing one or more dielectric material, and plasma etch.

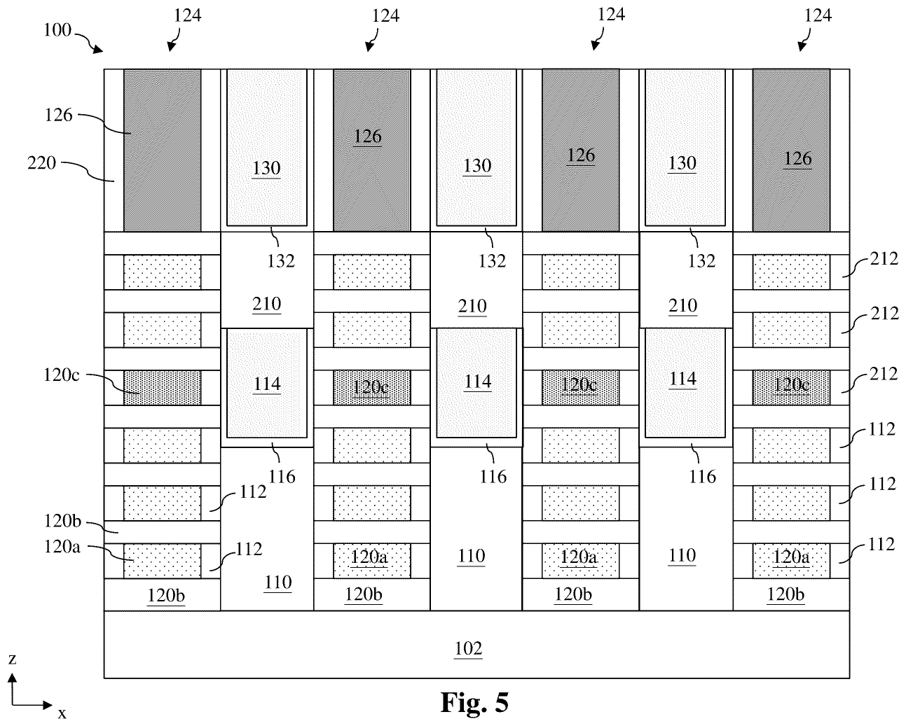

Referring to FIGS. 2A and 5, at operation 310, the method 300 epitaxially grows first S/D features 110 in the S/D trenches 128. At operation 312, the method 300 forms an S/D isolation layer 114, 116 over the first S/D features 110 by a method such as a procedure that includes depositing an etch stop layer 116, depositing a dielectric material layer 114, performing a chemical mechanical polishing (CMP) process, and etching back to recess the S/D isolation layer 114, 116.

Still referring to FIGS. 2A and 5, at operation 314, the method 300 epitaxially grows second S/D features 210 in the S/D trenches 128 and over the S/D isolation layer 114, 116.

Still referring to FIGS. 2B and 5, at operation 316, the method 300 forms an interlayer dielectric (ILD) layer 130 over the second S/D features 210 by a method such as a procedure that includes deposition and CMP. The ILD structure may further include an etch stop layer 132 having a dielectric material different from the bulk dielectric material of the ILD layer 130 to achieve etch selectivity.

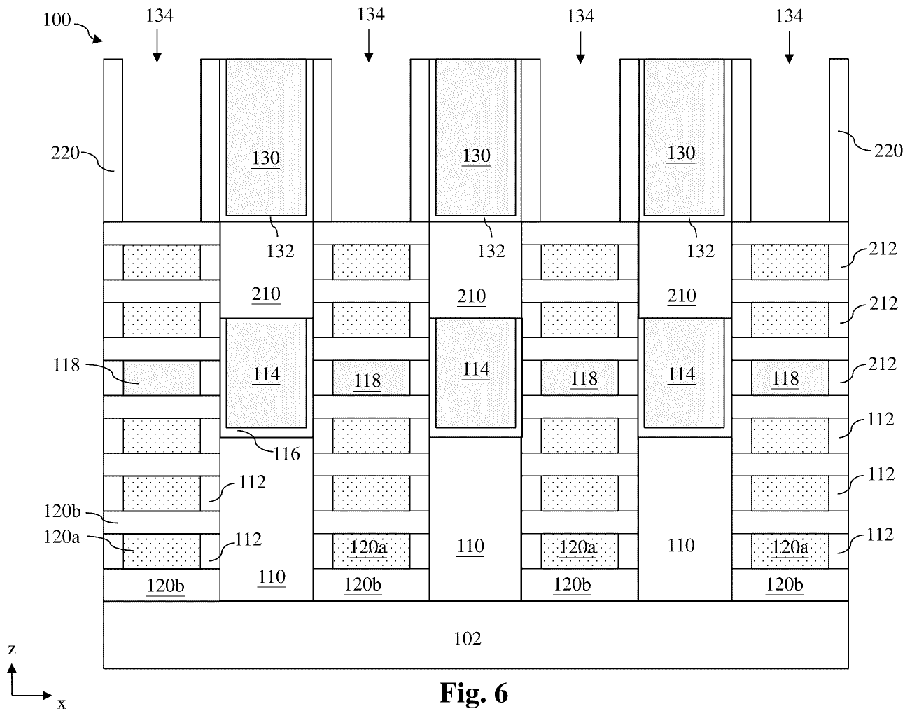

Referring to FIGS. 2B and 6, at operation 318, the method 300 removes dummy gate stacks 126 from the dummy gate structures 124, resulting in gate trenches 134. At operation 320, the method 300 removes the middle layer 120c and replaces it with a gate isolation layer 118.

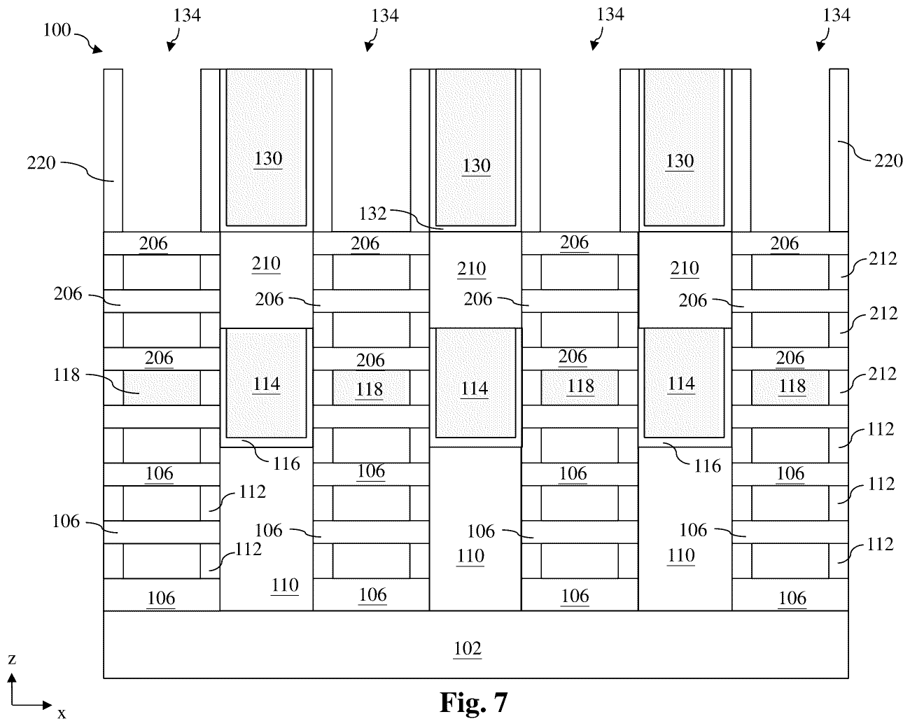

Referring to FIGS. 2B and 7, at operation 322, the method 300 forms suspended semiconductor channels 106, 206 by removing the remaining first semiconductor layers 120a and leaving the second semiconductor layers 120b as the suspended semiconductor channels 106, 206, respectively.

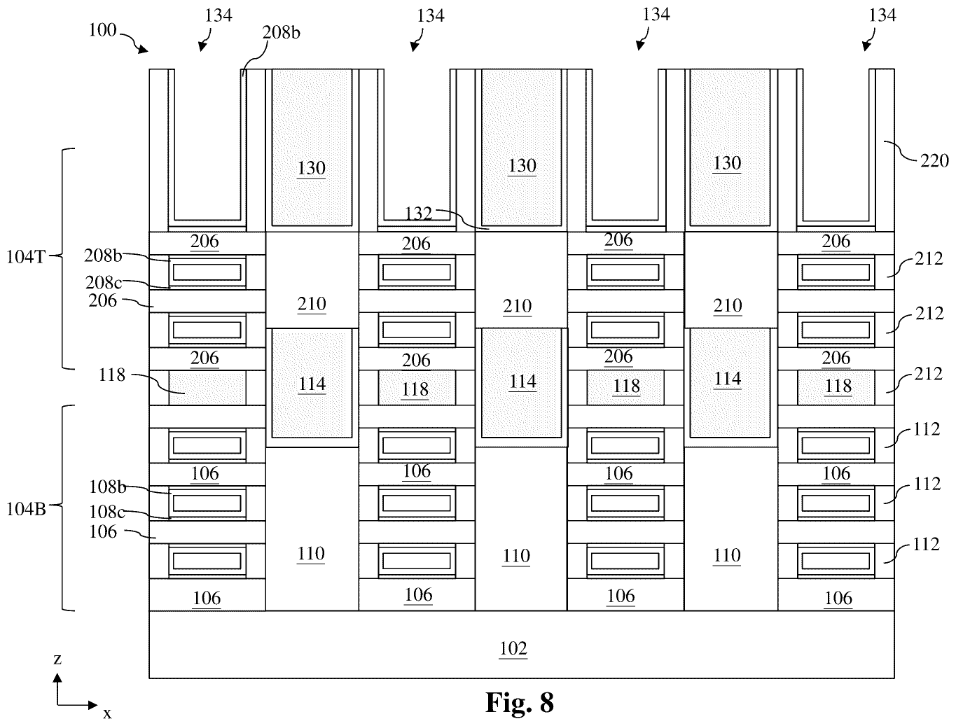

Referring to FIGS. 2B and 8, at operation 324, the method 300 forms gate dielectric layers (respectively referred to as 108b, 108c, and 208b, 208c) over the channel regions CR and wrapping around each of the suspended semiconductor channels 106, 206 or a subset thereof. Particularly, the dielectric layers 108c, 208c are interfacial layers; and the dielectric layers 108b, 208b are high-k dielectric material layers.

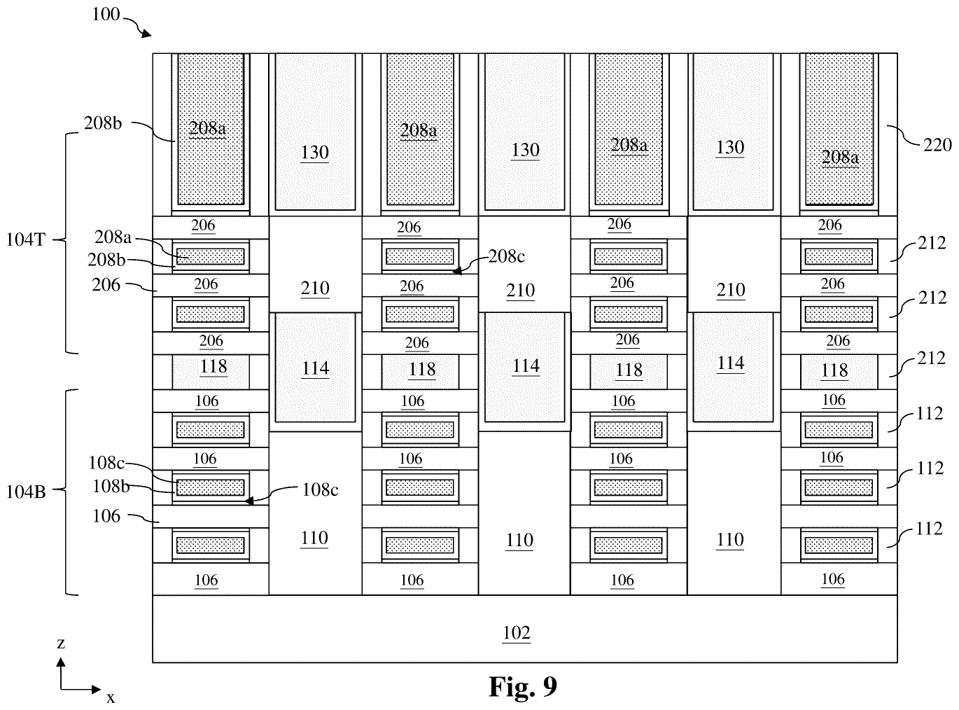

Referring to FIGS. 2B and 9, at operation 326, the method 300 may perform treatment, such as thermal annealing, to the gate dielectric layers. At operation 328, the method 300 deposits a gate metal over the gate dielectric layers. The gate metal may be referred to as a (metal) gate electrode 108a, 208a, and after forming the metal gate electrode, metal gate structures 108, 208 are formed. The gate electrode may include one or more metal layers with different composition. Furthermore, the material(s) for the gate electrodes 108a and 208a may have different material(s) such as having different work function metals.

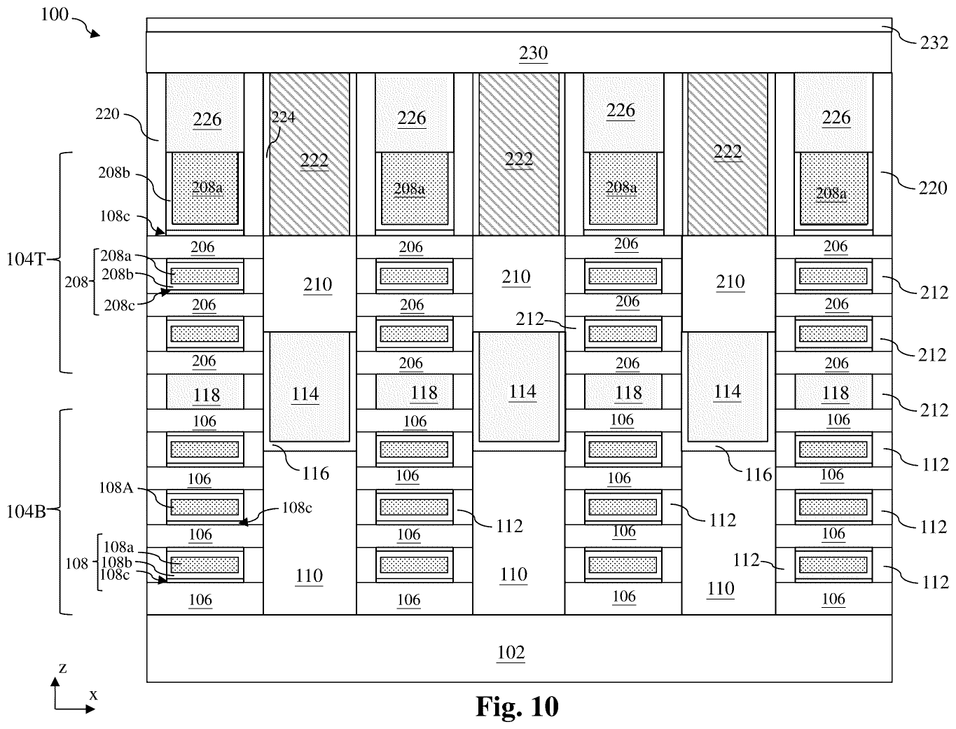

Referring to FIGS. 2B and 10, at operation 330, the method 300 forms S/D contacts 222, 224 over the first and second S/D features by a proper method, such as a procedure that includes patterning, deposition and CMP process. At operation 332, the method 300 may form the SAC features 226 self-aligned with the gate stacks 208 by a method, such as a procedure that includes etch to recess the gate stacks, depositing one or more dielectric material, and performing a CMP process. The method 300 may perform other operations to complete fabrication of the IC structure 100. Additional processing is contemplated by the present disclosure. Additional operations can be provided before, during, and after method 300, and some of the operations described can be moved, replaced, or eliminated for additional embodiments of method 300. For example, interconnect structure 230 may be further formed to couple various devices into an integrated circuit, and other feature such as a bonding layer 232 may be further formed on the interconnect structure to provide a bonding surface. In some embodiments, the interconnect structure 230 includes contacts, vias and metal lines distributed in multiple metal layers. In the copper interconnect, the conductive features include copper and may further include a barrier layer. The copper interconnect structure is formed by a damascene process. A damascene process includes depositing an ILD layer; patterning the ILD layer to form trenches; depositing various materials (such as a barrier layer and copper); and performing a CMP process. A damascene process may be a single damascene process or a dual damascene process. The deposition of the copper may include PVD to form a seed layer and plating to form bulk copper on the copper seed layer. Other metals, such as ruthenium, cobalt, tungsten or aluminum, may be used to form to form the interconnection structure.

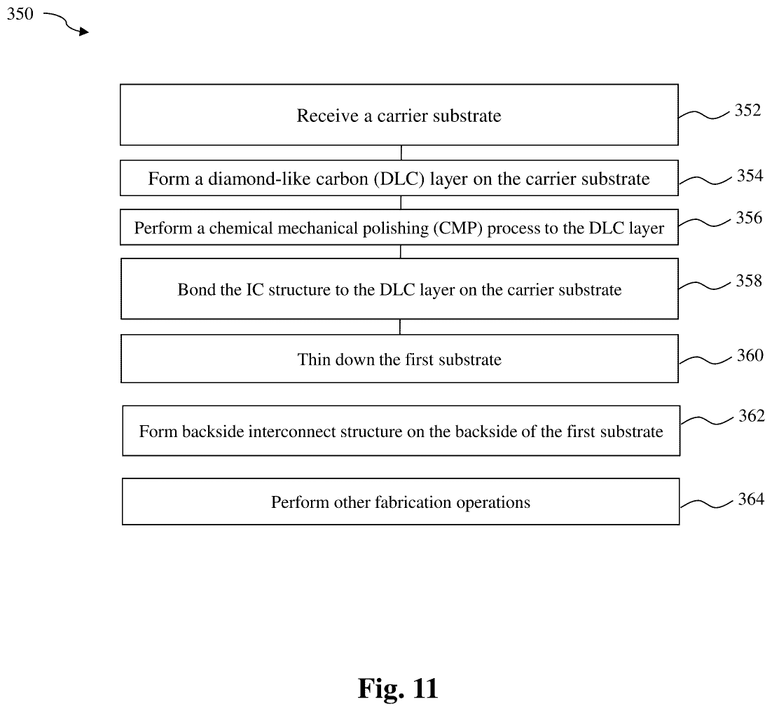

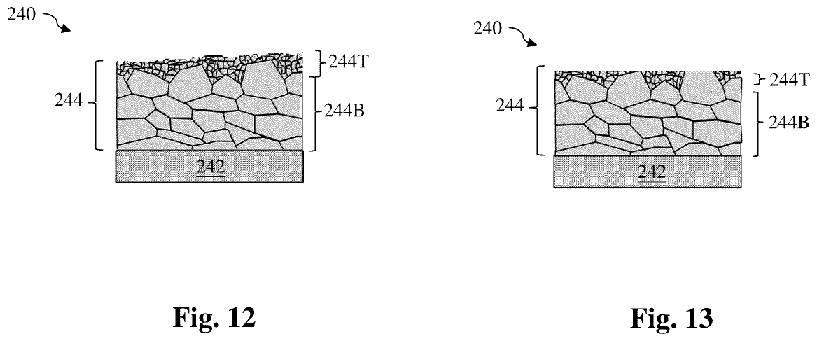

Such formed IC structure 100 is further bonded to a carrier substrate having a DLC layer formed by the disclosed method. This is further described in detail with reference to FIGS. 11, 12, 13 and 14 according to some embodiments. FIG. 11 is a flowchart of a method 350, FIGS. 12, 13 and 14 are sectional views of the workpiece 250 at various fabrication stages constructed according to some embodiments.

Referring to FIGS. 11 and 12, the method 350 proceeds to a carrier wafer structure 240. At operation 352, a carrier substrate 242 is received or provided. In some embodiments, the carrier substrate (or second substrate) 242 is a dielectric substrate such as a silicon nitride substrate, a silicon oxide substrate, or an aluminum oxide substrate. In some embodiments, the carrier substrate 242 is a semiconductor substrate such as a silicon substrate or alternatively a substrate with other suitable material(s).

At operation 354, a diamond-like carbon (DLC) layer 244 is deposited on the carrier substrate 242. In the disclosed embodiments, the DLC layer functions as a thermal dissipation structure and a bonding structure as well. Especially, the DLC layer 244 includes a bottom portion 244B and a top portion 244T with different grain sizes. The top portion 244T of the DLC layer 244 has fine grain sizes while the bottom portion 244B of the DLC layer 244 has large grain sizes greater than the fine grain sizes. The grain sizes usually have a distribution. In that sense, the average grain size of the top portion 244T is less than the average grain size of the bottom portion 244B of the DLC layer 244. In the disclosed embodiments, the bottom portion 244B of the DLC layer 244 includes grain sizes greater than 500 nm; and the top portion 244T of the DLC layer 244 includes grain sizes less than 500 nm. In furtherance of the embodiments, the bottom portion 244B of the DLC layer 244 includes grain sizes ranging between 500 nm and 5000 nm; and the top portion 244T of the DLC layer 244 includes grain sizes ranging between 5 nm and 500 nm. In some embodiments, the DLC layer 244 has a thickness ranging between 1 μm and 20 μm, and the top surface of the DLC layer 244 has a surface roughness less than 0.5 μm. The roughness is defined as the maximum height difference cross the top surface of the DLC layer. In some embodiments, the DLC layer 244 includes a graded structure with grain size gradually decreasing from bottom to top. Thus, a top surface of the DLC layer 244 is formed substantially planar.

The DLC layer 244 has higher thermal conductivity. However, the DLC is difficult to be planarize due to large grain size and high hardness. In the disclosed DLC layer 244, the top portion 244T has fine grain sizes with reduced roughness and improved flatness.

The process conditions to form the disclosed DLC layer is controlled to form the DLC layer with varying grain sizes with reduced surface roughness. The process conditions are described below according to some embodiments. In some embodiments, the DLC layer is formed by a suitable method, such as chemical vapor deposition (CVD), such as plasma CVD, other suitable method or a combination thereof. The CVD process is implemented with precursor includes carbon-containing chemical, such as benzene (C₆H₆)-nitrogen mixtures. During the deposition (such as CVD) process, the bottom portion is deposited with a first pressure (processing chamber pressure) P1 in a first duration and the top portion is deposited with a second pressure P1 in a second duration. P2 is greater than P2. In some embodiments, P1 is less than 5 Torr and the second pressure P2 is greater than 5 Torr. In some embodiments, the first pressure P1 ranges between 1 mTorr and 5 Torr, and the second pressure P2 ranges between 5 Torr and 50 Torr. In some embodiments, depositing the bottom portion of the DLC layer includes depositing the bottom portion of the DLC layer with a first deposition temperature T1; and the depositing the top portion of the DLC layer includes depositing the top portion of the DLC layer with a second deposition temperature T2 less than T1. In some embodiments, the first temperature T1 ranges between 400° C. and 1200° C. and the second temperature T2 ranges between 100° C. and 1200° C. In some embodiments, depositing each of the bottom portion and the top portion of the DLC layer includes performing a CVD process with a radio fervency (RF) power ranging between 50 W and 50 kW.

For the graded structure of the DLC layer 244, the process condition is controlled to continuously vary from the ranges of those parameters (such as the pressure and temperature) associated with the bottom portion to the ranges of those parameters associated with the top portion. Some parameters, such as RF power, may remain unchanged through the deposition of the whole process to form the DLC layer 244.

Referring to FIGS. 11 and 13, at operation 356, the method 350 perform a chemical mechanical polishing (CMP) process to further planarize the top surface of the DLC layer 244. As the roughness of the top surface of the DLC layer 244 is substantially reduced in the present disclosure, the CMP can easily and effectively further planarize the top surface with improved smoothness of the top surface of the DLC layer 244.

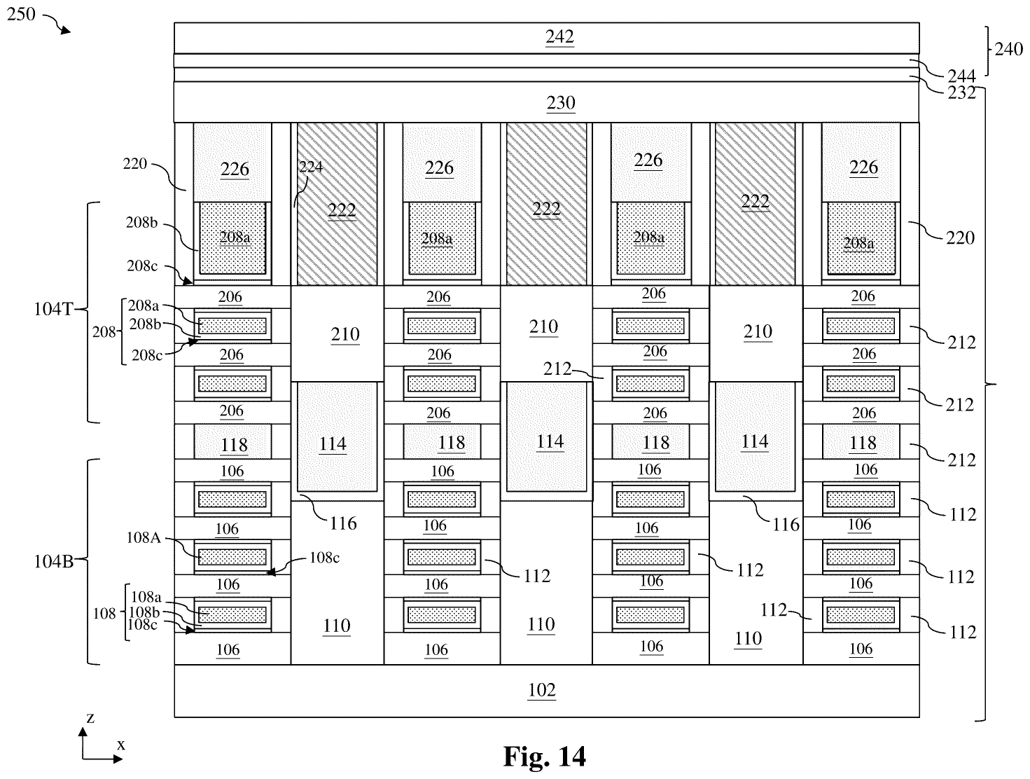

Referring to FIGS. 11 and 14, at operation 358, the method 350 bonds the carrier substrate 242 to the IC structure 100 in a frontside-to-frontside bonding mode such that the DLC layer 244 is bonded to the bonding layer 232 of the IC structure 100, resulting in a bonded IC structure 250. Due to the reduced surface roughness, the bonding strength and quality are enhanced.

After bonding, at operation 360, the method 350 thins down the first substrate 102 from the backside. At operation 362, a backside interconnect structure is formed on the backside of the IC structure 250. The method 350 may include other fabrication operations before, during or after the operations described above.

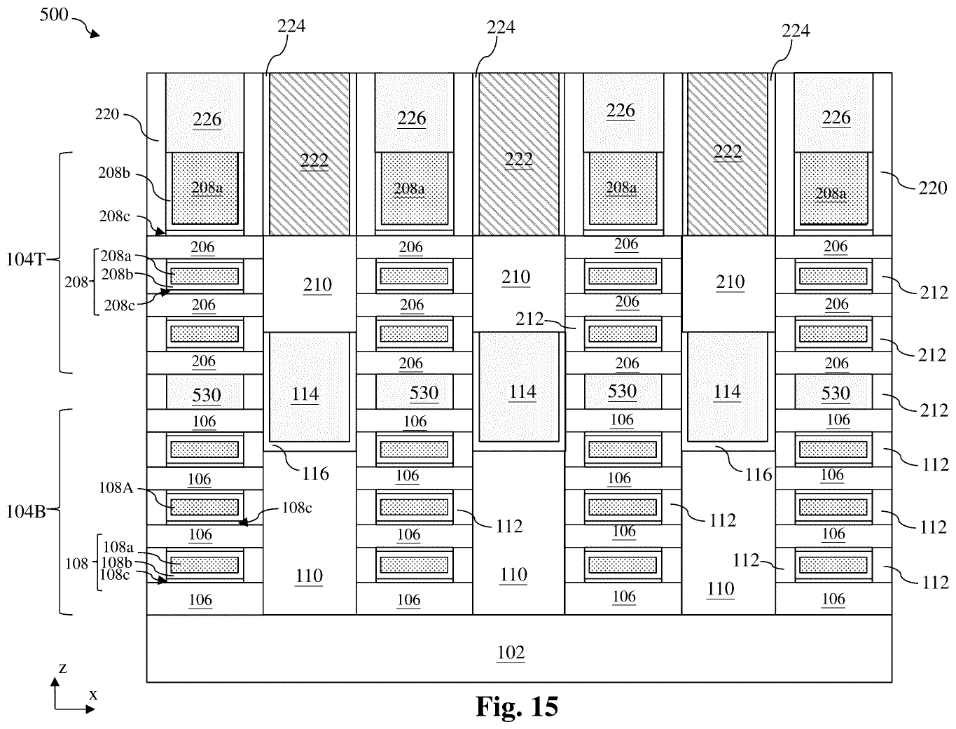

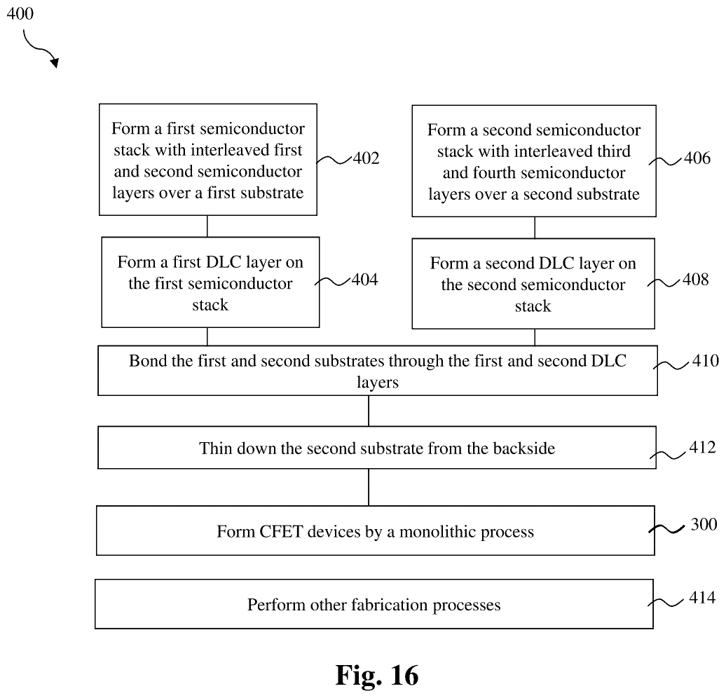

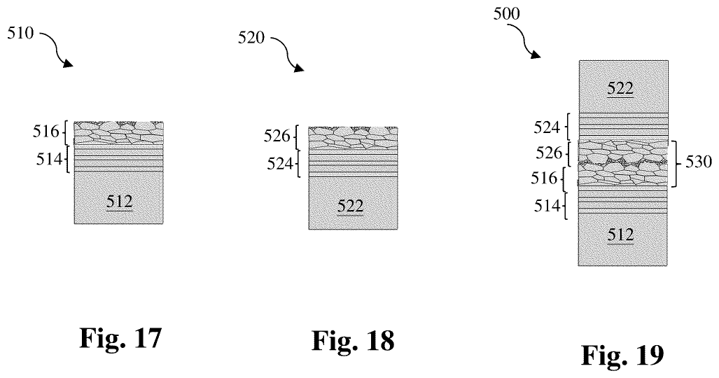

Other embodiments of an IC structure having the disclosed DLC layer are provided here. FIG. 15 illustrates a sectional view of an IC structure (workpiece) 500 having CFET devices in accordance with some embodiments. FIG. 16 is a flowchart of a method 400 constructed according to some embodiments. FIGS. 17-26 illustrate sectional views of an IC structure 500 at various fabrication stages and processed with the method 400 in accordance with some embodiments. The IC structure 500 and the method 400 are collectively described below. The IC structure 500 is different from the IC structure 250. Particularly, the DLC layer 530 is embedded in the CFET devices and functions as a bonding layer, a thermal dissipation layer, and additionally a gate isolation layer.

Referring to FIGS. 16 and 17, a bottom device structure 510 is prepared. At operation 402, a first stack 514 of first semiconductor layers of a first semiconductor material and second semiconductor layers of a second semiconductor material is formed on a first substrate 512 such that the first and second semiconductor layers are alternatively stacked. The first and second semiconductor materials are different in composition. For example, the first semiconductor material is silicon germanium, and the second semiconductor material is silicon. The second semiconductor layers eventually function as channels and are properly doped, such as doped with P-type dopant (e.g., boron) according to some embodiments.

At operation 404, a first DLC layer 516 is formed on the first stack 514. The DLC layer 516 is similar to the DLC layer 244 and the formation of the DLC layer 516 is similar to the formation of the DLC layer 244, such as illustrated in FIGS. 12 and 13. For example, the DLC layer 516 includes a bottom portion and a top portion with different grain sizes. The top portion of the DLC layer 516 has fine grain sizes while the bottom portion of the DLC layer 516 has large grain sizes greater than the fine grain sizes. In the disclosed embodiments, the bottom portion of the DLC layer 516 includes grain sizes greater than 500 nm; and the top portion of the DLC layer 516 includes grain sizes less than 500 nm. In furtherance of the embodiments, the bottom portion of the DLC layer 516 includes grain sizes ranging between 500 nm and 5000 nm; and the top portion of the DLC layer 516 includes grain sizes ranging between 5 nm and 500 nm. In some embodiments, the DLC layer 516 has a thickness ranging between 1 μm and 10 μm, and the top surface of the DLC layer 516 has a surface roughness less than 0.5 μm. In some embodiments, the DLC layer 516 includes a graded structure with grain size decreasing from bottom to top. Thus, a top surface of the DLC layer 516 is formed substantially planar. The formation of the DLC layer 516 includes a deposition with varying conditions as described in the DLC layer 244. A CMP process is applied to the DLC layer 516 to further planarize the top surface.

Referring to FIGS. 16 and 18, a top device structure 520 is prepared. At operation 406, a second stack 524 of third semiconductor layers of a third semiconductor material and fourth semiconductor layers of a fourth semiconductor material is formed on a second substrate 522 such that the third and fourth semiconductor layers are alternatively stacked. The third and fourth semiconductor materials are different in composition. For example, the third semiconductor material is silicon germanium, and the fourth semiconductor material is silicon. Especially, the third and fourth semiconductor materials in the second stack 524 may be different from the first and second semiconductor materials in the first stack 514. The fourth semiconductor layers eventually function as channels and are properly doped, such as doped with N-type dopant (e.g., phosphorous) according to some embodiments.

At operation 408, a second DLC layer 526 is formed on the second stack 524. The DLC layer 526 is similar to the DLC layer 516 and the formation of the DLC layer 526 is similar to the formation of the DLC layer 516. The similar descriptions are not repeated.

Referring to FIGS. 16 and 19, at operation 410, the bottom device structure 510 and the top device structure 520 are bonded together through the first DLC layer 516 and the second DLC layer 526. Due to the reduced surface roughness of the DLC layers 516, 526, the bonding strength is substantially enhanced. The first DLC layer 516 and the second DLC layer 526 are collectively function as a bonding interface and thermal dissipation, being referred to as the DLC layer 530.

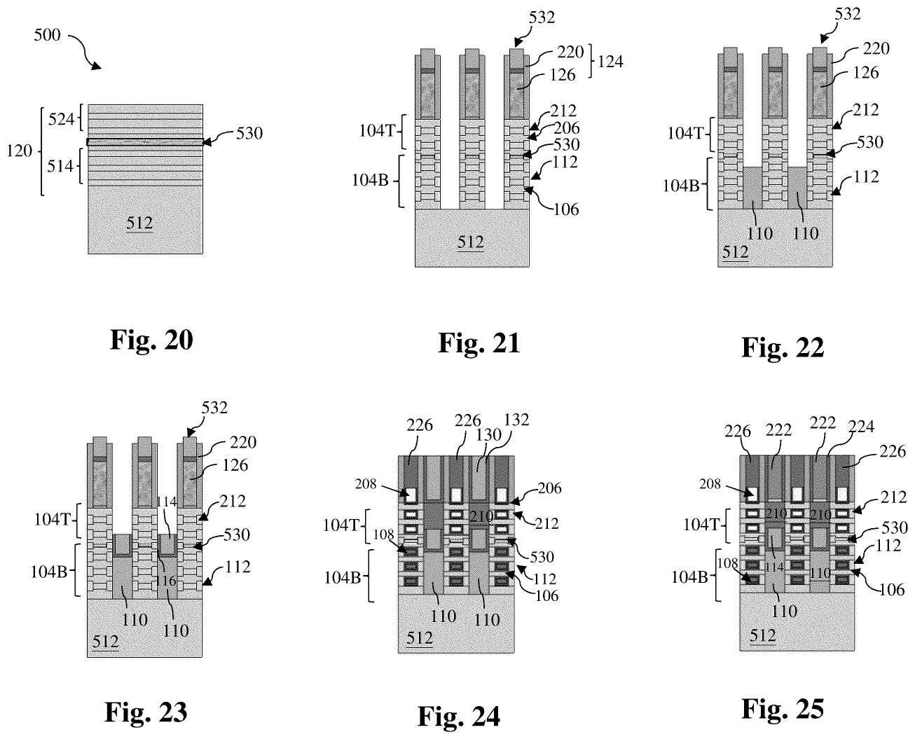

Referring to FIGS. 16 and 20, at operation 410, the second substrate 522 is thinned down such that the second stack 524 is exposed from the backside.

Thereafter, the method 400 proceeds to the operation 300 to form CFET devices by a monolithic process. The operation 300 is similar to the method 300 in FIGS. 2A-2B and includes multiple suboperations such as operations 302 through 332. In contrast to the IC structure 100, the first stack 514, the second stack 524, and the DLC layer 530 collectively function as the semiconductor stack 120 of the IC structure 100, such as the stack 120 illustrated in FIG. 4. The DLC layer 530 functions as the middle layer 120c of the IC structure 100. However, the DLC layer 530 can function as the gate isolation layer and remains in the final structure. In this case, the operation 320 in the method 300 is eliminated in the present method 400. The operation 302 includes patterning the semiconductor stack to form fin active regions. Various suboperations in the operation 300 are briefly described below. The similar descriptions are not repeated for simplicity.

Referring to FIGS. 16, 2A, and 21, at operation 302, the semiconductor stack 120 is patterned to form fin active regions. At operation 304, a dummy gate structure 124 is formed on the semiconductor stack 120 by deposition and patterning. The patterning process may use a hard mask 532. The hard mask 532 may include more than one material such as a silicon oxide film and a silicon nitride film. The dummy gate structure 124 includes gate stacks 126 and gate spacers 220 disposed on sidewalls of the gate stack. At operation 306, the S/D regions of the semiconductor stack 120 is recessed by etching to form S/D trenches. At operation 308, inner spacers 112, 212 are formed.

Referring to FIGS. 16, 2A, and 22, at operation 310, first (bottom) S/D features 110 are formed by epitaxial growth.

Referring to FIGS. 16, 2A, and 23, at operation 312, the S/D isolation layer 114, 116 is formed on the bottom S/D feature 110.

Referring to FIGS. 16, 2A, and 24, at operation 314, second (top) S/D features 210 are formed by epitaxial growth.

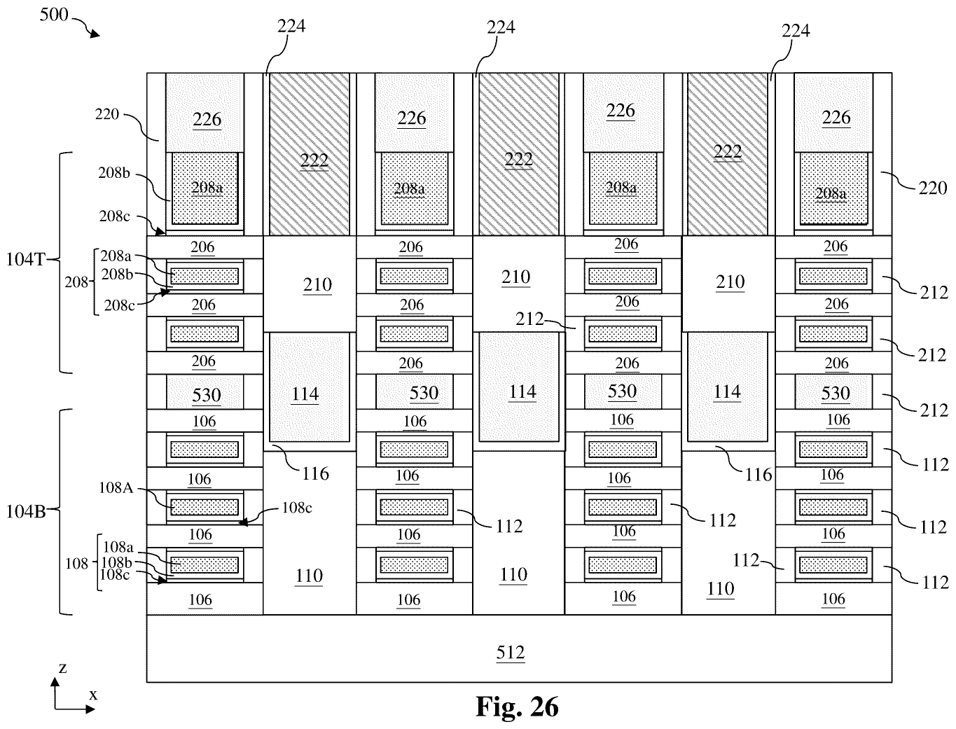

Still referring to FIGS. 16, 2B, and 24, at operation 316, the ILD layer 130, 132 is formed. For example, the second S/D features 210 are first recessed by selective etching; an etch stop layer 132 (such as silicon oxide) is deposited; a bull dielectric layer 130, such as low-k dielectric material, silicon oxide or a combination thereof, is deposited on the etch stop layer 132; and a CMP process is applied to planarize the top surface. At operation 318, the dummy gate stack 126 is removed by etching, resulting in gate trenches. At operation 322, the remaining first semiconductor layers are removed through the gate trenches by etching to form suspended channels 106, 206. Metal gates 108, 208 are further formed to wrap around the channels 106. Particularly, at operation 324, the gate dielectric layers (such as 108b/108c, 208b/208c) are formed. At operation 328, the gate electrodes (such as 108a, 208a) are formed, which are respectively labeled in FIG. 24 but are labeled in FIG. 26 for simplicity. At operation 332, the SAC 226 is formed on the gate electrodes 208a.

Referring to FIGS. 16, 2B, and 25, S/D contacts 222, 224 are formed over the S/D features 110, 210. For example, the ILD layer 130 is patterned to form contact holes; a barrier layer 224 is deposited in the contact holes; a metal material 222 is deposited in the contact trenches; and a CMP process may be further applied to planarize the top surface. The method 400 may include block 414 to perform other fabrication processes, such as forming interconnect structure.

Referring to FIG. 26, such formed IC structure 500 is further illustrated. The IC structure 500 is similar to the IC structure 100 in FIG. 1. Similar descriptions are not repeated for brevity. However, the DLC layer 530 is embedded in the CFET devices and functions as a gate isolation layer, a bonding interface and a thermal dissipation layer.

The present disclosure provides an IC structure having VFET devices and a DLC layer, and a method making the same according to various embodiments. The DLC layer functions as a bonding interface and a thermal dissipation layer and may additionally function as a gate isolation layer. Particularly, the DLC layer includes a bottom portion and a top portion with different grain sizes. The top portion of the DLC layer has fine grain sizes while the bottom portion of the DLC layer has large grain sizes greater than the fine grain sizes. The method to form the DLC layer includes various some parameters, such as pressure and temperature to vary the grain sizes. The disclosed DLC layer has reduced surface roughness and improved CMP process, which further enhance the performance and reliability of the IC structure, such as bonding strength.

In one example aspect, the present disclosure provides an integrated circuit (IC) structure. The IC structure includes a circuit structure having semiconductor devices formed on a first substrate, an interconnect structure over the semiconductor devices; and a thermal dissipation structure formed on a second substrate. The second substrate is boned to the circuit structure such that the thermal dissipation structure is interposed between the first and second substrates. The thermal dissipation structure includes a diamond-like carbon (DLC) layer. The DLC layer includes a bottom portion having large grain sizes and a top portion having fine DLC grain sizes.

In another example aspect, the present disclosure provides a method of making an integrated circuit (IC) structure. The method includes forming a circuit structure having semiconductor devices formed on a first substrate and an interconnect structure over the semiconductor devices; forming a thermal dissipation structure on a second substrate; and bonding the second substrate to the circuit structure such that the thermal dissipation structure is interposed between the first and second substrates. The forming a thermal dissipation structure includes forming a diamond-like carbon (DLC) layer that includes a bottom portion of the DLC layer having large DLC grain sizes and a top portion of the DLC layer having fine grain sizes.

In yet another example aspect, the present disclosure provides a method of making an integrated circuit (IC) structure. The method includes forming a first stack of first semiconductor layers of a first semiconductor material and second semiconductor layers of a second semiconductor material alternatively stacked on a first substrate; forming a first diamond-like carbon (DLC) layer on the first stack; forming a second stack of third semiconductor layers of the first semiconductor material and fourth semiconductor layers of the second semiconductor material alternatively stacked on a second substrate; forming a second first diamond-like DLC layer on the second stack; bonding the second substrate to the first substrate such that the first and second DLC layers are directly bonded together, wherein the first DLC layer has a first nonuniform structure and the second DLC layer has a second nonuniform structure; thinning down the first substrate; and forming complimentary field-effect transistors (CFETs) in the first and the second stacks.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. An integrated circuit (IC) structure, comprising:
a circuit structure having semiconductor devices formed on a first substrate, an interconnect structure over the semiconductor devices; and
a thermal dissipation structure formed on a second substrate, wherein
the second substrate is boned to the circuit structure such that the thermal dissipation structure is interposed between the first and second substrates,
the thermal dissipation structure includes a diamond-like carbon (DLC) layer, and
the DLC layer includes a bottom portion having large grain sizes and a top portion having fine DLC grain sizes.

2. The IC structure of claim 1, wherein
the bottom portion of the DLC layer includes grain sizes greater than 500 nm; and
the top portion of the DLC layer includes grain sizes less than 500 nm.

3. The IC structure of claim 1, wherein
the DLC layer has a thickness ranging between 1 μm and 20 μm; and
the top surface of the DLC layer has a surface roughness less than 0.5 μm.

4. The IC structure of claim 1, wherein grain sizes of the DLC layer decreases from the second substrate toward the circuit structure.

5. The IC structure of claim 4, wherein
the DLC layer includes a top surface and a bottom surface on the second substrate, and
the DLC layer includes a graded structure with the grain sizes continuously increase from the top surface to the bottom surface of the DLC layer.

6. The IC structure of claim 1, wherein the first substrate is a semiconductor substrate, and the second substrate is dielectric substrate.

7. The IC structure of claim 6, wherein the dielectric substrate is one of a silicon nitride substrate, a silicon oxide substrate and an aluminum oxide substrate.

8. The IC structure of claim 1, wherein the semiconductor devices include complimentary field-effect transistor (CFET) devices.

9. A method of making an integrated circuit (IC) structure, comprising:
forming a circuit structure having semiconductor devices formed on a first substrate and an interconnect structure over the semiconductor devices;
forming a thermal dissipation structure on a second substrate; and
bonding the second substrate to the circuit structure such that the thermal dissipation structure is interposed between the first and second substrates, wherein the forming a thermal dissipation structure includes forming a diamond-like carbon (DLC) layer that includes a bottom portion of the DLC layer having large DLC grain sizes and a top portion of the DLC layer having fine grain sizes.

10. The method of claim 9, wherein the forming a thermal dissipation structure on a second substrate includes
depositing the bottom portion of the DLC layer includes depositing the bottom portion of the DLC layer with a first pressure P1; and
depositing the top portion of the DLC layer includes depositing the top portion of the DLC layer with a second pressure P2 greater than P1.

11. The method of claim 10, wherein the first pressure P1 is less than 5 Torr and the second pressure P2 is greater than 5 Torr.

12. The method of claim 11, wherein
the first pressure P1 ranges between 1 mTorr and 5 Torr, and
the second pressure P2 ranges between 5 Torr and 50 Torr.

13. The method of claim 10, wherein
the depositing the first portion of the DLC layer includes depositing the first portion of the DLC layer with a first deposition temperature T1; and
the depositing the second portion of the DLC layer includes depositing the second portion of the DLC layer with a second deposition temperature T2 less than T1.

14. The method of claim 10, wherein
the depositing the first portion of the DLC layer includes depositing the first portion of the DLC layer with a first radio fervency (RF) power ranging between 50 W and 50 kW; and
the depositing the second portion of the DLC layer includes depositing the second portion of the DLC layer with a second RF power ranging between 50 W and 50 kW.

15. The method of claim 9, wherein the forming a thermal dissipation structure on a second substrate includes depositing the DLC layer with a pressure continuously varying from a first pressure to a second pressure greater than the first pressure.

16. The method of claim 9, wherein
the forming a circuit structure having semiconductor devices formed on a first substrate and an interconnect structure over the semiconductor devices includes forming a complimentary field-effect transistor (CFET) on the first substrate; and
the bonding the second substrate to the circuit structure includes bonding a dielectric substrate to the circuit structure.

17. The method of claim 9, wherein
the bottom portion of the DLC layer includes grain sizes greater than 500 nm; and
the top portion of the DLC layer includes grain sizes less than 500 nm.

18. A method of making an integrated circuit (IC) structure, comprising:
forming a first stack of first semiconductor layers of a first semiconductor material and second semiconductor layers of a second semiconductor material alternatively stacked on a first substrate;
forming a first diamond-like carbon (DLC) layer on the first stack;
forming a second stack of third semiconductor layers of the first semiconductor material and fourth semiconductor layers of the second semiconductor material alternatively stacked on a second substrate;
forming a second first diamond-like DLC layer on the second stack;
bonding the second substrate to the first substrate such that the first and second DLC layers are directly bonded together, wherein the first DLC layer has a first nonuniform structure and the second DLC layer has a second nonuniform structure;
thinning down the first substrate; and
forming complimentary field-effect transistors (CFETs) in the first and the second stacks.

19. The method of claim 18, wherein the forming a DLC layer on a first substrate includes
depositing the bottom portion of the first DLC layer with a first pressure P1; and
depositing the top portion of the first DLC layer with a second pressure P2 greater than P1.

20. The method of claim 19, wherein
the first pressure P1 ranges between 1 mTorr and 5 Torr, and
the second pressure P2 ranges between 5 Torr and 50 Torr.
